(19) United States
(12) Patent Application Publication
(10) Pub. No.: US 2009/0009184 A1
(43) Pub. Date: Jan. 8, 2009

(54) Test circuit and test method

(75) Inventor: Yutaka Saeki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/213,961

(22) Filed: Jun. 26, 2008

(30) Foreign Application Priority Data
Jul. 3, 2007 (JP) 2007-175038

(51) Int. Cl. G01R 31/02

(52) U.S. Cl. 324/537

(57) ABSTRACT

In a test circuit, a first N-channel transistor with an open drain is connected to a receiver in a test target integrated circuit and is configured to generate a first amplitude voltage signal in response to a first voltage drive signal. A second N-channel transistor with an open drain is connected to the receiver in the test target integrated circuit and is configured to generate a second amplitude voltage signal in response to a second voltage drive signal complimentary to the first voltage drive signal.

### INCORPORATION BY REFERENCE

This patent application claims priority on convention based on Japanese Patent Application No. 2007-175038 filed on Jul. 3, 2007. The disclosure thereof is incorporated herein by reference.

### BACKGROUND OF THE INVENTION

1. Field of the Invention

The present invention relates to a test circuit and a test method, and more particularly, to a test circuit for serial data transmission and a test method for the test circuit.

2. Description of Related Art

Data is transferred in a computer system by utilizing a communication system including a transmitter circuit and a receiver circuit. In recent years, a high-speed interface is required for transmission of enormous data. High-speed signal transmission is realized by using a low voltage differential signaling (LVDS) technique which uses current for a signal transmission, but consumption of a current is not always less in the LVDS technique. A mobile terminal needs be reduced in consumed power. For this reason, all of components, inclusive of a high-speed transmission circuit, are required to be reduced in consumed power.

Display data is transmitted between an internal circuit and a display panel in a cellular mobile phone. A hinge section between a housing and the display panel is narrow from the viewpoint of a design, and further data transmission lines need be reduced in number. One of techniques for solving the problem is Mobile-CMADS (Current Mode Advanced Differential Signaling), and CMADS is a trade mark. The Mobile-CMADS (hereinafter, to be abbreviated as “MCMADS”) is a high-speed serial interface standard for transmitting the display data to the display panel such as an LCD for the mobile terminal. A transmission clock signal is of a high frequency in the serial transmission, like the MCMADS. Therefore, a method of carrying out a test efficiently and accurately is demanded from the viewpoints of evaluation and product fabrication during development.

In conjunction with the above description, a semiconductor integrated circuit is disclosed in Japanese Patent Application Publication (JP-A-Heisei 9-167828). In this conventional technique, electric power is supplied based on an output circuit power supply/a test signal input pin OVDD/TIN in an output circuit in a normal operation mode in which a test mode input pin is in a low state. In contrast, the output circuit power source/the test signal input pin OVDD/TIN is used to input a test signal into an internal circuit in a test mode in which the test mode input pin is in a high state. An output buffer in the output circuit is of an open drain transistor system in the test mode, and therefore any power source is unnecessary to drive a signal to be outputted to an outside of the semiconductor integrated circuit.

Also, an IC operation mode setting method is disclosed in Japanese Patent Application Publication (JP-P2002-156425A). In this conventional technique, a drain of an output FET with an open drain driven by a CPU of an IC (i.e., a semiconductor integrated circuit) is connected to a display output port for LEDs for displaying internal data on the IC. Further, an input/output port is employed to allow the CPU to monitor a voltage Vds at the port through a buffer circuit. In addition, an external switch is provided in an external unit of the IC to close or open between an LED port and a ground. After resetting of a power supply of the IC and before start of a normal operation, the switch is turned on or off for the number of times corresponding to data to be set through an ON/OFF controller A in the external unit.

Here, the above two conventional techniques are similar to the MCMADS only in the point that an N-channel open drain transistor is used in test, but it is aimed to reduce the number of pins to be used in the test.

### SUMMARY

In a first aspect of the present invention, a test circuit includes a first N-channel transistor with an open drain, connected to a receiver in a test target integrated circuit and configured to generate a first amplitude voltage signal in response to a first voltage drive signal; and a second N-channel transistor with an open drain, connected to the receiver in the test target integrated circuit and configured to generate a second amplitude voltage signal in response to a second voltage drive signal complimentary to the first voltage drive signal.

In a second aspect of the present invention, a test method of a test target integrated circuit by a tester, is achieved by generating first and second voltage drive signals which are complimentary; and by. generating first and second amplitude voltage signals in response to the first and second voltage drive signals, by using first and second N-channel transistors with an open drain, respectively.

N-channel open drain transistors are mounted on a test card, and connected to an MCMADS receiver in MCMADS test. Further, the N-channel open drain transistors are complementarily driven by using a voltage output from a tester. In this manner, an MCMADS receiver circuit can be readily tested in a high accuracy by achieving a test environment of the same current drive as in an actual operation of an MCMADS transmission system.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a circuit diagram showing a data transmission circuit;

FIG. 2 is a block diagram showing an LVDS testing technique;

FIG. 3 is a circuit diagram schematically showing an MCMADS transmission system;

FIG. 4 is a block diagram showing a test circuit according to a first embodiment of the present invention;

FIGS. 5A to 5E are diagrams showing waveforms according to the present invention; and

FIG. 6 is a block diagram showing the test circuit according to a second embodiment of the present invention.

### DESCRIPTION OF THE PREFERRED EMBODIMENTS

Hereinafter, a test circuit of the present invention will be described in detail with reference to the attached drawings.

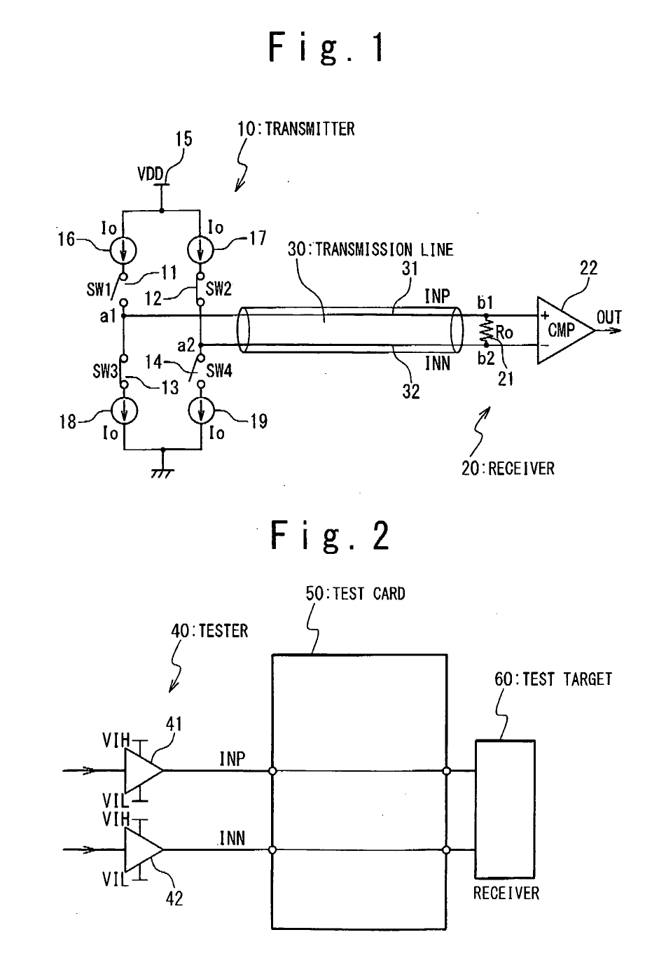

FIG. 1 is a circuit diagram showing a circuit configuration of the test circuit in a low voltage differential signaling (LVDS) technique serving as a high-speed transmitter equivalent to MCMADS. With reference to FIG. 1, a transmission circuit in the LVDS technique includes a transmitter (Tx) 10 and a receiver (Rx) 20. Also, the transmitter (Tx) 10 and the receiver (Rx) 20 are connected to each other via a transmission channel pair 30 for signals INP and INN. The transmission channel pair 30 includes a transmission channel INP 31 and a transmission channel INN 32. The transmission channel INP 31 is provided for the signal INP, and the transmission channel INN 32 is provided for the signal INN. Here, the transmitter (Tx) 10 is provided with switches SW1 11, SW2 12, SW3 13 and SW4 14, a power supply voltage VDD 15, and constant current sources (Io) 16, 17, 18 and 19.

The switches (SW1) 11 and (SW3) 13 are connected in series, and the switches (SW2) 12 and (SW4) 14 are connected in series. A voltage is applied to the switches (SW1) 11 and (SW2) 12 from the VDD 15, and the switches (SW3) 13 and (SW4) 14 are connected to the ground, that is, are grounded. Here, the constant current source (Io) 16 is interposed between the power supply voltage VDD 15 and the switch (SW1) 11, the constant current source (Io) 17 is interposed between the power supply voltage VDD 15 and the switch (SW2) 12, the constant current source (Io) 18 is interposed between the switch (SW3) 13 and the ground, and the constant current source (Io) 19 is interposed between the switch (SW4) 14 and the ground. It should be noted that the transmission channel INP 31 is connected to a node a1 between the switch (SW1) 11 and the switch (SW3) 13, and the transmission channel INN 32 is connected to a node a2 between the switch (SW2) 12 and the switch (SW4) 14.

The receiver (Rx) 20 is provided with a resistor (Ro) 21 and a comparator (CMP) 22. The resistor (Ro) 21 is a terminator resistor, and is interposed between a node b1 connected to the transmission channel INP 31 and a node b2 connected to the transmission channel INN 32. A positive input (+) of the comparator (CMP) 22 is connected to the transmission channel INP 31 via the node b1, and a negative input (−) of the comparator (CMP) 22 is connected to the transmission channel INN 32 via the node b2.

FIG. 2 is a diagram showing a test method of a receiver (Rx) in the LVDS technique. A transmission circuit in the LVDS technique shown in FIG. 2 is provided with a tester 40, a test card 50 and an IC 60 as a test target as a semiconductor integrated circuit. The tester 40 includes a first buffer 41 and a second buffer 42. The first buffer 41 outputs the signal INP to the test card 50, and the second buffer 42 outputs the signal INN to the test card 50. The test card 50 receives the signals INP and INN and outputs them to the test target 60. Here, the test target 60 represents the receiver (Rx) 20 shown in FIG. 1.

As shown in FIGS. 1 and 2, the transmission circuit in the LVDS technique uses a transmission channel pair for the signals INP and INN. Here, the transmitter (Tx) is a drive current supply source whereas the receiver (Rx) is a differential voltage detecting circuit. In other words, the drive current supply source and the differential voltage detecting circuit are assigned to the transmitter (Tx) 10 and the receiver (Rx) 20, respectively. In this case, small amplitude voltage signals of about 100 mV are generated on the transmission channel INP 31 and the transmission channel INN 32. Therefore, the receiver (Rx) 20 can be tested with respect to signal detection by directly supplying a differential voltage signal to the transmission channels from the tester 40, as shown in FIG. 2. In FIG. 2, the signals INP and INN outputted from the drivers of the tester 40 are supplied directly into the test target 60 via the test card 50. Accordingly, the tester 40 needs to apply the small amplitude voltage signals to the signals INP and INN.

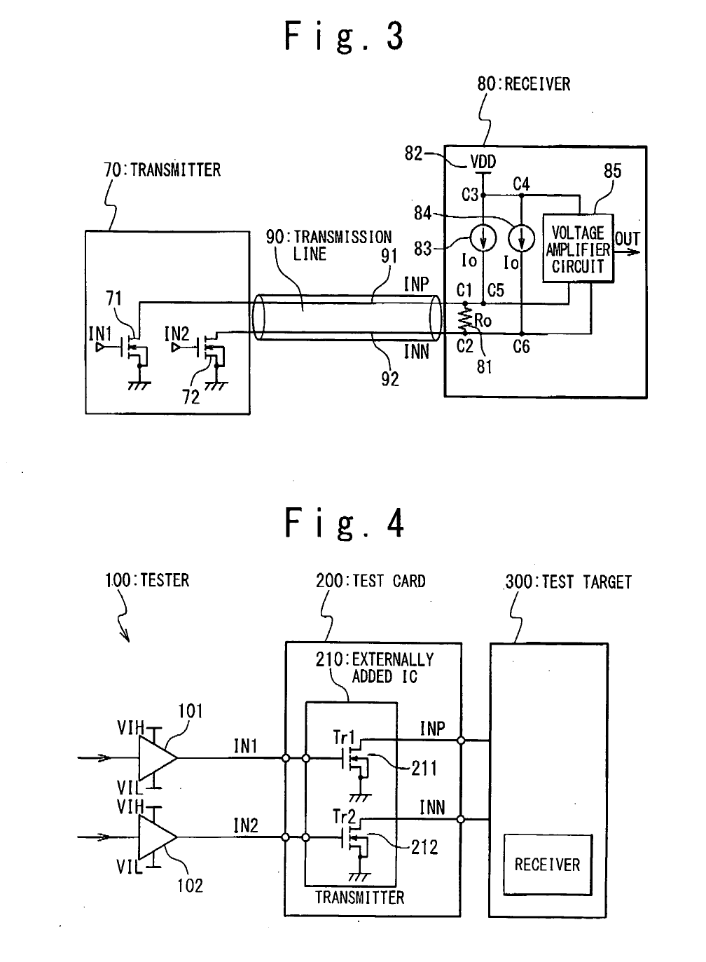

FIG. 3 shows a circuit configuration of MCMADS. The MCMADS shown in FIG. 3 includes a transmitter (Tx) 70 and a receiver (Rx) 80. In addition, the transmitter (Tx) 70 and the receiver (Rx) 80 are connected to each other via a transmission channel pair 90. The transmission channel pair 90 includes the transmission channel INP 91 and the transmission channel INN 92. The transmission channel INP 91 is provided for the signal INP, and the transmission channel INN 92 is provided for the signal INN.

Here, the transmitter (Tx) 70 is provided with an N-channel open drain transistor 71 and another N-channel open drain transistor 72. The receiver (Rx) 80 is provided with a resistor (Ro) 81, a power supply VDD 82, constant current sources (Io) 83 and 84, and a voltage amplifying circuit 85. The resistor (Ro) 81 is a terminator resistor, and is interposed between a node c1 connected to the transmission channel INP 91 and a node c2 connected to the transmission channel INN 92. The power supply VDD 82 is connected to each of the constant current source (Io) 83 and 84 and the voltage amplifying circuit 85. A node c3 is provided between the power supply VDD 82 and the constant current source (Io) 83, and a node d4 is connected to the node c3. Both of the constant current sources (Io) 84 and the voltage amplifying circuit 85 are connected to the node c4. The constant current source (Io) 83 is connected to a node c5 connected to the node c1. The constant current source (Io) 84 is connected to a node c6 connected to the node c2. The voltage amplifying circuit 85 is connected to the nodes c5 and c6, and amplifies the signals INN and INP to output a signal OUT.

Like the LVDS, the MCMADS transmission circuit uses a transmission channel pair for the signals INP and INN. However, unlike the LVDS shown in FIG. 1, both of drive current sources and a differential voltage detecting (amplifying) circuit are provided inside the receiver (Rx) 20. As a consequence, the receiver (Rx) 80 has both of functions of detecting amplitude voltages and the differential voltage on the transmission channels, but cannot directly receive voltage signals from a tester 100, unlike the LVDS technique. In case of testing MCMADS by this method, a drive current source is on a side of the tester 100, which is different from an actual operation. That is to say, a voltage waveform is generated on the transmission channel by a current flowing from the receiver (Rx) 80 side to the transmitter (Tx) 10 side in the actual operation. However, in the above-mentioned test, the voltage waveform is generated on the transmission channel by supplying current from the transmitter (Tx) 10 side. In this manner, the receiver (Rx) 80 may be more affluently operated than in the actual operation.

FIG. 4 shows the test circuit according to a first embodiment of the present invention. The MCMADS shown in FIG. 4 is provided with a tester 100, a test card 200 and a test target (semiconductor integrated circuit) 300 to be tested. The tester 100 supplies signals IN1 and IN2 into the test card 200. The test card 200 supplies the signals INP and INN into the test target 300. Here, the tester 100 includes a first buffer 101 and a second buffer 102. The first buffer 101 outputs the signal IN1, and the second buffer 102 outputs the signal IN2. The test card 200 is provided with an externally added IC 210. The externally added IC 210 includes an N-channel open drain transistor (Tr1) 211 and an N-channel open drain transistor (Tr2) 212. The N-channel open drain transistor (Tr1) 211 receives the signal IN1 and outputs the signal INP. In contrast, the N-channel open drain transistor (Tr2) 212 receives the signal IN2 and outputs the signal INN. Here, a test card represents a tool used in testing the test target as the semiconductor integrated circuit. The test card has needles which are brought into contact with respective pads of the semiconductor integrated circuit so as to apply a test signal outputted from the tester to the pads of the semiconductor integrated circuit.

It should be noted that the transmitter (Rx) 70 shown in FIG. 3 may be used as the externally added IC 210. In such a case, the N-channel open drain transistor (Tr1) 71 corresponds to the N-channel open drain transistor (Tr1) 211 while the N-channel open drain transistor (Tr1) 72 corresponds to the N-channel open drain transistor (Tr1) 212. In addition, if the test target 300 includes the receiver (Rx) 80 shown in FIG. 3, the circuit configuration shown in FIG. 3 is encompassed in the circuit configuration shown in FIG. 4 as it is.

In FIG. 4, the voltage drive signals IN1 and IN2 outputted from the tester 100 are received by the externally added IC 210 attached to the test card 200. The externally added IC 210 has N-channel open drain transistors. A pair of the N-channel open drain transistors are needed for the differential transmission. It is necessary for the externally added IC 210 to include the pair of N-channel open drain transistors so as to prevent any variation between the N-channel open drain transistors. The voltage signals IN1 and IN2 outputted from the tester 100 drive the N-channel open drain transistors in the externally added IC 210 to generate the signals INP and INN by turning on or off paths between input terminals of the MCMADS receiver in the test target 300 and the ground. It should be noted that the signals INP and INN are often small amplitude voltage signals of about 100 mV on the transmission channel pair in the MCMADS. The small amplitude voltage signal is generated with current to be supplied from the test target 300 on the reception side since the N-channel open drain transistors are disposed on the transmission side of the MCMADS, the externally added IC 210 functions as the transmitter. As a consequence, the test can be achieved under a same operational condition as that of the actual operation of the MCMADS, and further the input signals IN1 and IN2 supplied from the tester 100 are in a CMOS level. Thus, the test can be performed without any trouble even if the tester 100 cannot output the small amplitude voltage of the 100 mV.

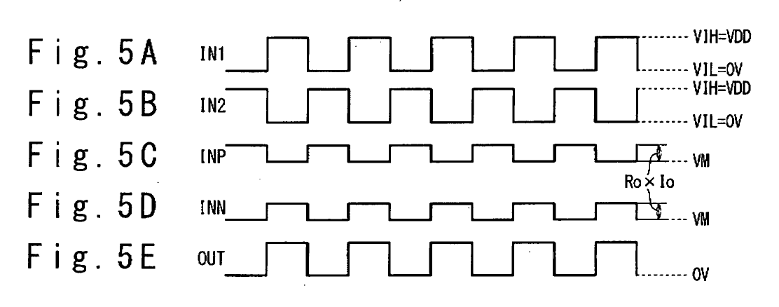

FIGS. 5A to 5E are diagrams showing waveforms at a time of the test shown in FIG. 4. Here, FIG. 5A illustrates a waveform of the signal IN1; FIG. 5B, a waveform of the signal IN2; FIG. 5C, a waveform of the signal INP; FIG. 5D, a waveform of the signal INN; and FIG. 5E, a waveform of a signal OUT.

The signals IN1 and IN2 outputted from the tester 100 are complementary: namely, the signal IN1 is in the high level (VIH is equal to a power supply voltage VDD) whereas the signal IN2 is in an L level (VIL is equal to the ground voltage of 0 V); and the signal IN1 is in the low level whereas the signal IN2 is in the high level.

When the signal IN1 is in the high level whereas the signal IN2 is in the low level, the N-channel open drain transistor (Tr1) 211 of the externally added IC 210 is turned on whereas the N-channel open drain transistor (Tr2) 212 is turned off. Consequently, all of current of 2×Io from the current sources shown in FIG. 3 flow in the N-channel open drain transistor (Tr1) 211, so that the transmission channel INP becomes VM whereas the transmission channel INN becomes Ro×Io+VM. The voltage Ro×Io is generated when-the constant current Io flows through the resistor Ro in the MCMADS receiver 80 shown in FIG. 3. Here, the voltage VM means the low level on the transmission channel INP or INN, and the voltage on the high level becomes higher by Ro×Io than the voltage on the low level. A differential voltage signal generated in response to the signals INP and INN is amplified in a voltage amplifier circuit 85 shown in FIG. 3, and then the high level signal (power supply voltage VDD) is outputted as the signal OUT as shown in FIG. 5E.

When the signal IN1 is in the low level whereas the signal IN2 is in the high level, the N-channel open drain transistor (Tr1) 211 in the external IC 210 is turned off whereas the N-channel open drain transistor (Tr2) 212 is turned on. Consequently, the entire current 2×Io in the current sources shown in FIG. 3 flows through the N-channel open drain transistor (Tr2) 212, so that the transmission channel INP becomes Ro×Io+VM whereas the transmission channel INN becomes VM. The differential voltage signal generated in response to the signals INP and INN is amplified by the voltage amplifier circuit 85 shown in FIG. 3, and then the low level signal (0 V) is outputted as the signal OUT as shown in FIG. 5E.

In the test, the input signals IN1 and IN2 are made to correspond to an output signal OUT, and whether or not the signals are correctly transmitted is checked.

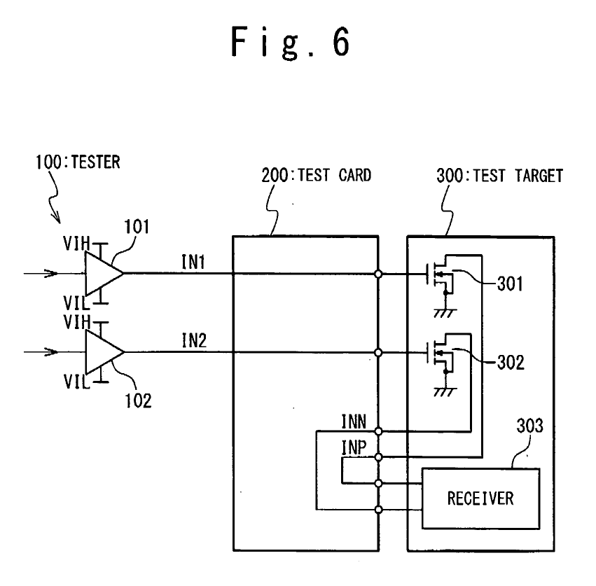

Next, the test circuit according to a second embodiment of the present invention will be described with reference to FIG. 6. The MCMADS shown in FIG. 6 is provided with the tester 100, the test card 200 and the test target (semiconductor integrated circuit) 300. The tester 100 supplies the signals IN1 and IN2 into the test card 200. The test card 200 receives the signals IN1 and IN2 and supplies the signals INP and INN to the test target 300. Here, the tester 100 includes the first buffer 101 and the second buffer 102. The first buffer 101 outputs the signal IN1, and the second buffer 102 outputs the signal IN2. The test target 300 includes an N-channel open drain transistor (Tr1) 301, an N-channel open drain transistor (Tr2) 302, and a receiver (Rx) 303. The N-channel open drain transistor (Tr1) 301 receives the signal IN1 and outputs the signal INP. Also, the N-channel open drain transistor (Tr2) 302 receives the signal IN2 and outputs the signal INN. In addition, the signals INP and INN are received by the receiver (Rx) 303 via the test card 200. Here, the signals INP and INN may be received by the receiver (Rx) 303 with passing through the test card 200. In this case, it is preferable that the signals INP and INN should be received by the receiver (Rx) 303 after passing through the test card 200 once, in order to detect voltages of the signals INP and INN.

It should be noted that the test target 300 may include the transmitter (Tx) 70 and the receiver (Rx) 80 shown in FIG. 3. In this case, the N-channel open drain transistor 71 shown in FIG. 3 corresponds to the N-channel open drain transistor (Tr1) 301; the N-channel open drain transistor 72 shown in FIG. 3 corresponds to the N-channel open drain transistor (Tr2) 302; and the receiver (Rx) 80 shown in FIG. 3 corresponds to the receiver (Rx) 303. In other words, the circuit configuration shown in FIG. 6 may encompass the circuit configuration shown in FIG. 3 as it is.

In FIG. 6, the N-channel open drain transistors (i.e., the externally added IC 210) corresponding to a transmission side shown in FIG. 4 is incorporated in the test target 300. Therefore, the N-channel open drain transistors do not need to be mounted on the test card 200. Like in FIG. 4, in the test, the signals IN1 and IN2 outputted from the tester 100 are complimentary, namely, the signal IN1 is in the high level (VIH is equal to power supply voltage VDD) while the signal IN2 is in the low level (VIL is equal to the ground of 0 V), and the signal IN1 is in the low level while the signal IN2 is in the high level.

The present invention relates to a test technique of the receiver (Rx) in the MCMADS. The test technique is needed in shipping a product on which the receiver (Rx) of the MCMADS is mounted. If the test technique according to the present invention is carried out in shipping the product, the test accuracy is improved more than a case that the test technique according to the present invention is not carried out. Thus, it is preferable to carry out the test according to the present invention in an accurately testing.

The present invention will be further described. In a test method of an input circuit of the communication apparatus, which is provided with a switch for connecting the output terminal as an output circuit to the ground, and a circuit for current-driving the input terminal as an input circuit. In a general-purpose test circuit (i.e., an LSI tester), a switch disposed independently of the general-purpose test circuit is used as a test output circuit connected to the input circuit. Also, a complementary transmission signal is turned on or off. A switch may be provided in a device to be tested. In this way, the test is carried out in substantially an actual operation by connecting the external pair transistors (i.e., the N-channel open drain transistors) to the test card and converting an amplitude voltage.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A test circuit comprising:
a first N-channel transistor with an open drain, connected to a receiver in a test target integrated circuit and configured to generate a first amplitude voltage signal in response to a first voltage drive signal; and
a second N-channel transistor with an open drain, connected to said receiver in said test target integrated circuit and configured to generate a second amplitude voltage signal in response to a second voltage drive signal complimentary to the first voltage drive signal.

2. The test circuit according to claim 1, wherein the first and second amplitude voltage signals are generated based on drive currents from said receiver in said test target integrated circuit.

3. The test circuit according to claim 2, wherein said receiver comprises a voltage amplifier circuit configured to amplify a differential voltage signal between the first and second amplitude voltage signals.

4. The test circuit according to claim 3, wherein when the first voltage drive signal is in a first voltage level and the second voltage drive signal is in a second voltage level, said voltage amplifier circuit outputs a signal with the first voltage level.

5. The test circuit according to claim 1, wherein one of the first and second amplitude voltage signals is an amplitude signal of 100 mV.

6. The test circuit according to claim 2, wherein said first and second N-channel transistors are provided in said test target integrated circuit.

7. The test circuit according to claim 2, wherein said first and second N-channel transistors are provided in a circuit externally added to a test card.

8. The test circuit according to claim 1, wherein said first and second voltage drive signals are supplied from a tester.

9. A test method of a test target integrated circuit by a tester, comprising:
generating first and second voltage drive signals which are complimentary; and
generating first and second amplitude voltage signals in response to the first and second voltage drive signals, by using first and second N-channel transistors with an open drain, respectively.

10. The test method according to claim 9, wherein said generating first and second amplitude voltage signals comprises:
generating the first and second amplitude voltage signals based on drive currents supplied from a receiver in said test target integrated circuit.

11. The test method according to claim 10, further comprising:
generating a test output signal by amplifying a differential voltage signal between the first and second amplitude voltage signals.

12. The test method according to claim 11, wherein said generating a test output signal comprises:
generating the test output signal with a first voltage level, when the first voltage drive signal is in the first voltage level and the second voltage drive signal is in a second voltage level.

13. The test method according to claim 9, wherein said generating first and second voltage drive signals comprises:
generating the first and second voltage drive signals in said tester, and
said generating first and second amplitude voltage signals comprises:
generating the first and second amplitude voltage signals in a test card to supply to said test target integrated circuit.

14. The test method according to claim 9, wherein said generating first and second voltage drive signals comprises:
generating the first and second voltage drive signals in said tester, and
said generating first and second amplitude voltage signals comprises:
generating the first and second amplitude voltage signals in said test target integrated circuit to supply to said test target integrated circuit through a test card.

15. The test method according to claim 9, wherein said first and second voltage drive signals are supplied from a tester.
